(19) United States
(12) Patent Application Publication
(10) Pub. No.: US 2022/0131206 A1
(43) Pub. Date: Apr. 28, 2022

(54) Cooling device for cooling an energy accumulator and/or electronic assembly and method of manufacturing the same

(71) Applicant: Liebherr-Components Biberach GmbH, Biberach an der Riss (DE)

(72) Inventor: Markus EICHLER, Waldshut (DE)

(73) Assignee: Liebherr-Components Biberach GmbH, Biberach an der Riss (DE)

(21) Appl. No.: 17/451,085

(22) Filed: Oct. 15, 2021

Related U.S. Application Data
(63) Continuation of application No. PCT/EP2020/061322, filed on Apr. 23, 2020.

(30) Foreign Application Priority Data
Apr. 26, 2019 (DE) 10 2019 110 870.5

(51) Int. Cl. H01M 10/613; H01M 10/6556; H01M 10/6554

(52) U.S. Cl. CPC H01M 10/613; H01M 10/6554; H01M 10/6556

(57) ABSTRACT

The invention relates to a cooling device for cooling an energy accumulator and/or electronic assembly, comprising a preferably plate-shaped heat sink in whose interior at least one coolant channel is formed, wherein the heat sink comprises two sheet metal blanks cohesively joined onto each other surface to surface, wherein one sheet metal blank has a channel-shaped bulge that bulges out of the joining plane of the two sheet metal blanks with about the same wall thickness, is connected to the other sheet metal blank only at its edge, and forms the coolant channel.

### CROSS-REFERENCE TO RELATED APPLICATIONS

This application is a continuation of International Patent Application Number PCT/EP2020/061322 filed Apr. 23, 2020, which claims priority to German Patent Application Number DE 10 2019 110 870.5 filed Apr. 26, 2019, the contents of which are incorporated herein by reference in their entireties.

### BACKGROUND

The present invention generally relates to the cooling of energy accumulator and/or electronic assemblies. The invention on the one hand relates to a cooling device for cooling such energy accumulator and/or electronic assemblies with a preferably plate-shaped heat sink in whose interior at least one coolant channel is formed. The invention furthermore also relates to the energy accumulator and/or electronic assembly comprising such a cooling device. Furthermore, the invention also relates to a method of manufacturing such a cooling device.

In modern energy accumulators, which for example can employ double-layer capacitors, the power density, the useful life and the compactness are increasingly determined by the possible dissipation of the heat loss. Due to the high power densities, large amounts of heat must be dissipated, as otherwise the energy accumulators attain too high temperatures which damage or shorten the useful life. The dissipation of large amounts of heat however is not easy, as the energy accumulators are of increasingly small design, so that a sufficient contact surface to heat exchangers or heat sinks no longer is available. Said problems are even aggravated by the fact that the heat transfer and accessibility of energy accumulators such as double-layer capacitors and batteries such as lithium-ion batteries often is possible only at the poles of the energy accumulators.

Similar problems as regards the heat dissipation are found not only in energy accumulators, but als in other electronic assemblies, which process high power densities with increasingly smaller dimensions, such as for example throttles, switching systems, converters or other power-electronic components.

To on the one hand achieve an insulation and on the other hand a good heat transfer at the same time, thermally conductive foils sometimes are applied to the poles of energy accumulators or to the connection contacts of power-electronic components. Thus, the heat transfer is effected from the connection pole via the thermally conductive foil to the heat sink of the cooling device. Due to the heat dissipation into the cooling water, the heat sink, which frequently is configured in the form of a cooling plate, must be developed especially for the connection poles and be manufactured by rather expensive methods. For example, such heat sinks often are manufactured or constructed from two metal plates, wherein a cooling channel pattern is milled into a usually thicker base plate, which pattern then is sealed by mounting a thinner cover plate and fluid-tightly connecting the same to the base plate by vacuum soldering. What is quite expensive per se not only is the milling out of the cooling channels and the vacuum soldering, but above all it is difficult to contour the heat sink in such a way that both connection poles of an energy accumulator or electronic module can be connected to the heat sink. As for example both poles of a double-layer capacitor must be cooled in order to be able to sufficiently dissipate the heat loss, the material and manufacturing expenditure is very high and costly. In a similar way, the poles of batteries such as LION batteries must also be cooled.

Proceeding therefrom, it is the object underlying the present invention to create an improved cooling device, an improved energy accumulator and/or electronic assembly comprising such a cooling device, and an improved method of manufacturing the same, which avoid disadvantages of the prior art and develop the latter in an advantageous way.

According to the invention, said object is achieved by a cooling device according to claim 1, an energy accumulator and/or electronic assembly according to claim 14, and a method of manufacturing a cooling device according to claim 22. Preferred embodiments of the invention are subject-matter of the dependent claims.

### SUMMARY

It is therefore proposed to construct the heat sink from at least two sheet metal blanks, which are cohesively joined onto each other surface to surface by a roll-bonding method, wherein portions of the sheet-metal blanks corresponding to the course of the coolant channel are omitted from the joining process, and after the joining process a sheet metal blank is bulged in the area of the unjoined portions corresponding to the course of the coolant channel in order to form the coolant channel. With approximately constant wall thickness, the channel-shaped bulge can bulge out of the joining plane of the two sheet metal blanks, be connected to the other sheet metal blank only at its edge, and form the coolant channel.

In particular, said bulge can be formed by inflation in the region of the unjoined portions of the sheet metal blanks. The unjoined sheet metal blank portions can be pierced and be charged with compressed air or a pressurized fluid that enters into unjoined portions between the two sheet metal blanks and urges the same apart so that said bulge is formed.

To ensure that in the roll-bonding joining process said portions, in which coolant channels are to be formed later on, are omitted from the cohesive joining process, at least one of the two sheet metal blanks can be provided with a release agent before the joining process, which release agent is provided corresponding to the course of the coolant channel to be formed, so that the joining of the two sheet metal blanks is partially inhibited in the region of the release agent.

Said release agent can be a release coating, for example, which is applied onto one or both sheet metal blanks corresponding to the pattern or course of the coolant channel, for example by screen printing. Alternatively or in addition, a relief-like embossment can also be incorporated into one or both of the sheet metal blanks as a release agent, for example in the form of a groove-shaped depression corresponding to the course of the coolant channel, so that the two sheet metal blanks do not bond to each other in the region of the embossed structure.

As a release agent, for example, graphite can be applied onto one of the sheet metal blanks.

Advantageously, the sheet metal blanks forming the heat sink are substantially completely connected to each other surface to surface except for the bulges forming the coolant channels, wherein said surface-to-surface connection can be of the cohesive type. With the exception of the coolant channels, the flat sides of the sheet metal blanks can completely be cohesively connected to each other, so that the surface-to-surface cohesive connection is omitted only in the region of the coolant channels. In this way, a high stability can be achieved with thin heat sink thicknesses. In general, a very small thickness of the preferably plate-shaped heat sink can be achieved, as it is not necessary to take account of necessary wall thicknesses for welding processes or no additional solder needs to be applied.

In an advantageous embodiment of the invention, the at least one bulge, which forms the at least one coolant channel, can be harmoniously bulged in cross-section, in particular have a harmoniously curved undulation, which gently rises towards the edges of the bulge, i.e. towards the channel edges connected to the other sheet metal blank, bulges more strongly in the center and again gently slopes again towards the opposite edge so that the coolant channel has a harmoniously curved contour as seen in cross-section. In particular, the coolant channel can be formed by inflation. The coolant channel is formed by shaping the sheet metal blank in particular only after the joining process, so that the sheet metal blank maintains substantially the same wall thickness also in the region of the bulge and hence in the region of the coolant channel. Other than in coolant channels formed by milling out a metal plate, the sheet metal blank exhibits no major change in wall thickness in the region of the bulge.

In an advantageous development of the invention, the at least one coolant channel is formed by only one unilateral bulge. While the sheet metal blank is bulged in the unjoined portions, which were provided with a release agent, and bulges out of the joining plane, the other sheet metal blank can be of flat design and/or have a bulge-free surface. In particular, said other sheet metal blank can have a flat surface and/or form a flat plate.

The heat sink, however, need not form a flat plate in a mathematical sense, but can also form a curved plate depending on the configuration of the energy accumulator and/or electronic assembly to be cooled, wherein the curvature can be uniaxial or biaxial. For example, the heat sink can be slightly barrel-vaulted when the connection poles of the electronic components to be cooled for example are arranged along a slightly shell-shaped curved contour. In particular, however, the heat sink can be formed substantially flat and merely have said channel-shaped bulges for forming the coolant channels as irregularities.

In the case of an only unilateral bulge of the coolant channels, the non-bulged sheet metal blank substantially can be contoured completely flat or, with a slightly bulged contour, have an envelope area that corresponds to the surface.

In an advantageous development of the invention, sheet metal blanks having the same wall thickness can be joined to each other by a roll-bonding process. Regardless of the joining process, the joining plane or area between the two sheet metal blanks can extend approximately centrally in the cross-sectional area or through the cross-sectional area, as seen in a cross-section of the heat sink. Proceeding from the joining plane or area, the heat sink can extend approximately equally far towards opposite sides.

In an advantageous development of the invention, the cooling device can comprise two preferably plate-shaped heat sinks in order to be able to cool the energy accumulator or electronic assembly from opposite sides. The two heat sinks can be connected to each other and held against each other by traction elements so that a gap-shaped clearance is formed between the two heat sinks, in which the energy accumulator or electronic assembly can be arranged, in particular clamped. Said traction elements hold the two heat sinks at a distance which substantially corresponds to the outside dimensions of the energy accumulator or electronic assembly, so that said assembly can be fitted precisely between the two heat sinks.

As an alternative to two separate heat sinks, there can also be used one heat sink that has a substantially U-shaped contour with two legs spaced apart from each other, in particular approximately parallel to each other, between which the energy accumulator or electronic assembly to be cooled can be accommodated. For example, a plate-shaped heat sink can be shaped to obtain the U-shaped contour along a folding or bending line or along two of such folding or bending lines, so that the heat sink encloses the energy accumulator or electronic assembly from three sides.

In terms of configuration, however, it is easier to use two separate heat sinks which are placed on the assembly to be cooled from opposite sides and are held by said traction elements.

Said traction elements for example can be pull rods which can directly or indirectly engage said heat sinks.

In particular, a holding plate or holding frame can be placed on the respective heat sink, which holding frame or holding plate can be fixed by said pull rods. Said holding plate or holding frame is placed on that side of the heat sink which faces away from the assembly to be cooled.

When two heat sinks are placed on opposite sides of the assembly to be cooled in the way mentioned above, holding plates or holding frames can be placed on the sides of the heat sinks facing away from each other, which are held against each other by traction elements and/or are tensioned towards each other in order to clamp or fix the energy accumulator or electronic assembly between the heat sinks.

Advantageously, said traction elements can be positively held, in particular latched in place at the heat sinks and/or said holding plates or frames.

In a development of the invention, the energy accumulator and/or electronic assembly can comprise a plurality of energy accumulator and/or electronic modules which can be positioned in a matrix-shaped arrangement.

Advantageously, said plurality of energy accumulator and/or electronic assemblies can each be cooled by a common heat sink which is placed against the group of energy accumulator or electronic modules from one side. In particular, said energy accumulator or electronic modules can be arranged between two plate-shaped heat sinks which accommodate the plurality of energy accumulator or electronic modules between themselves in a sandwich-like manner.

Said energy accumulator modules can comprise capacitors, in particular double-layer capacitors, and/or have connection poles arranged on opposite sides, which connection poles each are connected to a heat sink of the cooling device. Said energy accumulator modules can also comprise batteries, in particular lithium-ion batteries or lithium batteries, whose connection poles each are connected to a heat sink of the cooling device.

In an advantageous development of the invention, said heat sinks can have cooling connection surfaces which each contact a connection pole of an energy accumulator or electronic module to be cooled and are shape-adapted to said connection pole. When the connection poles have a surface contoured in the shape of a mushroom head, for example, the heat sinks can include dish-like depressions shaped corresponding to the mushroom-head-shaped contour. The shape-adapted connection surfaces of the heat sink can improve the heat transfer from the connection poles into the heat sink, as the heat transfer surface is increased.

When said connection poles for example have protruding pin-like connection journals, the heat sinks can also comprise bore-like or hole-like recesses into which the connection pole journals can be plugged.

Regardless of shape-adapted connection surfaces, the surface of the heat sink can be provided with a coating in order to improve the insulation and/or the heat transfer. For example, a ceramic coating, in particular in the form of a ceramic paint, can be applied onto the heat sink surface in order to improve the electrical insulation and the heat transfer at the same time. Alternatively or in addition to such a ceramic coating, a plasma coating of oxides can also be provided. In particular, a coating with aluminum oxide (Al₂O₃) can be applied onto the heat sink surface in order to achieve an excellent electrical insulation with a very good thermal conductivity at the same time.

Advantageously, a connection of a heat sink plate made of aluminum and the oxide can be effected very easily and technically efficiently by plasma coating, wherein in principle, however, other coating methods are also applicable. The surface is extremely hard, very uniformly flat and mechanically very stable, and thus in particular also optimally suited for mobile applications.

Alternatively or in addition, a preferably insulating thermally conductive foil can be applied onto the heat sink in order to achieve a good heat transfer with an insulating effect at the same time.

### BRIEF DESCRIPTION OF THE DRAWINGS

The invention will be explained in detail below with reference to a preferred exemplary embodiment and associated drawings. In the drawings:

FIG. 1: shows a side view of an energy accumulator assembly, which in a sandwich-like manner is arranged between two plate-shaped heat sinks that are clamped onto the energy accumulator assembly by pull rods,

FIG. 2: shows a top view of one of the plate-shaped heat sinks, which illustrates the course of the coolant channel in the interior of the heat sink, and

FIG. 3: shows a schematic representation of the method steps for manufacturing the plate-shaped heat sinks from the preceding Figures.

### DETAILED DESCRIPTION

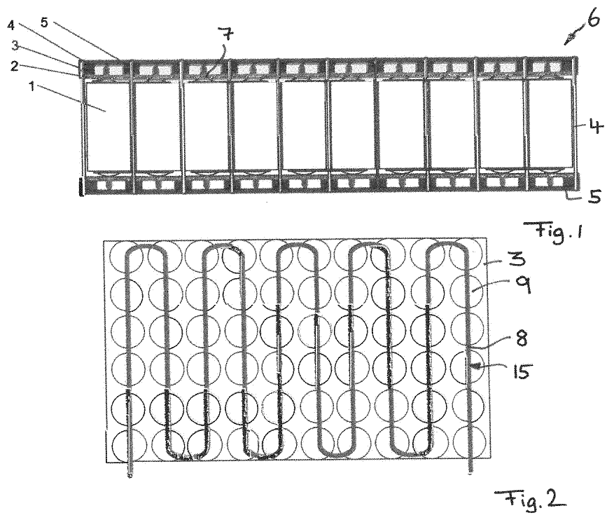

As is shown in FIGS. 1 and 2, the cooling device 6 can be configured to cool a row or matrix of energy accumulators 1 or similar electronic, in particular power-electronic components at their connection poles 7, wherein it would also be possible, however, to only cool an individual energy accumulator or electronic component 1 by means of the cooling device 6.

As is shown in FIGS. 1 and 2, the cooling device 6 can include two plate-shaped heat sinks 3 which are attached to said arrangement of energy accumulators 1 from opposite sides in order to contact their connection poles 7 and provide for a heat transfer from the connection poles 7 to the heat sink 3.

Advantageously, the energy accumulators 1 can be arranged or clamped between the two plate-shaped heat sinks 3 in a sandwich-like manner. The two heat sinks 3 can be spaced apart from each other or be held against each other by means of traction elements 4 for example in the form of pull rods, wherein the traction elements 4 in particular can hold the heat sinks 3 together on the opposite sides of the energy accumulators 1.

To hold the heat sinks 3 against the energy accumulators 1, holders 5, which can be configured as holding plates or holding frames, can be placed on the sides of the heat sinks 3 facing away from the energy accumulators 1, wherein said holders 5 are held together by means of the traction elements 4, in particular in such a way that the holders 5 hold the heat sinks 3 against the front sides or outer sides of the energy accumulators 1.

Advantageously, said traction elements 4 can be positively connected, advantageously be latched to the holders 5, wherein however other connecting means such as screws or bayonet locks or the like can also be provided.

Said holders 5 can be configured for example in the form of inexpensive steel sheets which are placed on the heat sinks 3, wherein however other types of holders 5, for example in the form of a strut framework, can also be used.

As is shown in FIG. 2, the plate-shaped heat sinks 3 can comprise one or more coolant channels 8 in their interior, wherein for example a meandrous coolant channel winding back and forth can be provided, which guides the coolant over all connecting surfaces or external poles 7 of the energy accumulators 1 connected therewith. Instead of the meandrous coolant channel 8 shown in FIG. 2, however, other coolant channel patterns can also be provided, which can include a plurality of separate and/or branching coolant channels.

Corresponding to the arrangement of the energy accumulators 1 and their connection poles 7, the respective heat sink 3 can have a corresponding arrangement of contact surfaces 9 which contact the energy accumulators 1 at their connection poles 7 and can be formed on a surface, in particular on a flat side of the plate-side heat sink 3.

Said two heat sinks 3 advantageously each are constructed from two sheet metal blanks 10, 11 which over a full or large surface are cohesively connected to each other in order to form the heat sink 3. Said sheet metal blanks 10 and 11 advantageously can be aluminum sheets of preferably small wall thickness, i.e. the material thickness is only a fraction of the length and/or the width of the corresponding sheet metal blank 10, 11, for example less than 10% or less than 5% of the length and/or the width.

Possibly, more than two sheet metal blanks can also be joined onto each other, in order to form for example a three-layer or multilayer heat sink 3 and/or manufacture a heat sink 3 with a coolant channel pattern in different layers.

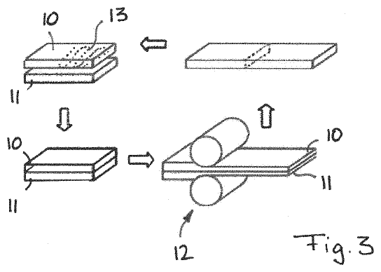

As is illustrated in FIG. 3, the sheet metal blanks 10 and 11 can be cohesively joined together by a roll-bonding process, wherein the sheet metal blanks 10 and 11 can be placed one on top of the other with their large flat sides and can pass through a roller assembly 12. In particular, rotating rollers can be used to apply high pressure and, if necessary, temperature to the sheet metal blanks 10 and 11 lying one on top of the other in order to cohesively connect the sheet metal blanks 10 and 11 at the surfaces adjoining each other. The two sheet metal blanks 10 and 11 connected to each other can jointly have a material thickness or heat sink thickness which can be reduced as compared to the sum of the thicknesses of the initial sheet metal blanks, cf. FIG. 3.

As is illustrated in FIG. 3, the two sheet metal blanks 10 and 11 for example can be cut from an aluminum sheet in order to then be placed one on top of the other. To promote or support the roll-bonding joining process, the blank surfaces to be placed one on top of the other can be machined, for example be brushed or prepared in some other way.

To provide for the formation of the coolant channels 8 in a future manufacturing step, a release agent 13 for example in the form of a graphite-containing paint can be applied onto at least one sheet metal blank 10 corresponding to the course of the desired coolant channel, wherein said release agent 13 can be applied for example by a screen printing process.

The release agent 13 is applied onto that surface of the sheet metal blank 10 which is to be joined with the opposite surface of the other sheet metal blank 11, in order to omit portions of the sheet metal blank surfaces adjoining each other, which correspond to the future pattern of the desired coolant channels, from the joining process. Possibly, said release agent 13 can also be applied onto both sheet metal blanks 10 and 11, wherein the release agent 13 need not necessarily be applied on that sheet metal blank which is to be bulged later on by inflation.

The sheet metal blanks 10 and 11 prepared in this way are then placed one on top of the other and then conveyed through the roller assembly 10, by which they are cohesively connected to each other at high pressure with a possibly additional application of temperature, which in particular in a process of continuous roller pressure can be effected with continuous rotation of the rollers and/or with continuous advance of the sheet metal blank pack relative to the roller assembly 12.

By pressurizing the rollers, the sheet metal blanks 10 and 11 are cohesively connected to each other surface to surface, namely with the exception of the portions that have been provided with the release agent.

In a succeeding method step, the sheet metal blanks 10 and 11 cohesively connected to each other surface to surface then are pierced in the region of the coolant channels 8 to be formed, i.e. in the region of the applied release agent pattern, so as to be able to blow in compressed air in the region of the release agent 13 between the sheet metal blanks 10 and 11 in order to inflate the coolant channels 8.

Advantageously, only one of the sheet metal blanks 10 is bulged out, while the other sheet metal blank 11 can be maintained flat, for example by applying a flat stamping tool against which the connected sheet metal blanks can be urged by a counter-stamp, which can have cutouts in the region of the coolant channels 8 to be formed.

By inflating the pierced release agent patterns 13, harmoniously curved coolant channels 8 are formed, for example in the form of the meandering coolant channel 8 of FIG. 2, wherein one of the sheet metal blanks 10 bulges out in the form of a groove, wherein said bulge can bulge out of the joining plane.

To increase the electrical insulation and at the same time achieve a very good thermal conductivity, the sheet metal blanks 10 and 11 and/or the constructed plate-shaped heat sink 3 can be provided with a coating, for example with a ceramic coating for instance in the form of a ceramic paint or a coating with aluminum oxide Al₂O₃. In particular, a plasma coating of one or both sheet metal blanks 10 and 11 and/or of the heat sink 3 constructed therefrom can be provided with an oxide, in particular in the form of said aluminum oxide Al₂O₃. Thereby, a very hard, uniformly flat and mechanically very stable surface can be achieved, which at the same time achieves an excellent electrical insulation with a very good thermal conductivity at the same time.

1. A cooling device for cooling an energy accumulator and/or electronic assembly, the cooling device comprising:
a plate-shaped heat sink in whose interior at least one coolant channel is formed, wherein the plate-shaped heat sink comprises a first sheet metal blank and a second sheet metal blank, wherein the first sheet metal blank and the second sheet metal blank are adhesively joined to each other surface to surface, wherein the first sheet metal blank has a channel-shaped bulge that bulges out of the joining plane between the first sheet metal blank and the second sheet metal blank with about the same wall thickness, is connected to the second sheet metal blank only at its edge, and forms the at least one coolant channel.

2. The cooling device of claim 1, wherein the first sheet metal blank and the second sheet metal blank are adhesively joined to each other surface to surface with a roll-bonding joining connection.

3. The cooling device of claim 1, wherein the channel-shaped bulge has a harmoniously curved wave contour as seen in cross-section.

4. The cooling device of claim 1, wherein the channel-shaped bulge is formed by inflation.

5. The cooling device of claim 1, wherein only the first sheet metal blank has the channel-shaped bulge, and wherein the second sheet metal blank is flat and/or has a bulge-free surface.

6. The cooling device of claim 1, wherein the adhesively joined first sheet metal blank and the second sheet metal blank form a flat heat sink plate with the exception of the channel-shaped bulge.

7. The cooling device of claim 1, wherein the first sheet metal blank and the second sheet metal blank have substantially the same wall thickness and the joining plane or surface between the first sheet metal blank and the second sheet metal blank extends approximately centrally through a cross-sectional area of the plate-shaped heat sink.

8. The cooling device of claim 1, wherein the first sheet metal blank and the second sheet metal blank are aluminum sheets.

9. The cooling device of claim 1, wherein the plate-shaped heat sink comprises a first plate-shaped heat sink, wherein the cooling device further comprises a second plate-shaped heat sink comprising at least one coolant channel and sheet metal blanks joined to each other, wherein the first plate-shaped heat sink and the second plate-shaped heat sink are arranged at a distance from each other and by traction elements are held against each other and on the energy accumulator and/or electronic assembly so that a gap between the first plate-shaped heat sink and the second plate-shaped heat sink corresponds to dimensions of the energy accumulator and/or electronic assembly, and wherein the energy accumulator and/or electronic assembly is clamped between the first plate-shaped heat sink and the second plate-shaped heat sink.

10. The cooling device of claim 9, wherein on surfaces facing apart from each other holders are seated on the first plate-shaped heat sink and the second plate-shaped heat sink, and wherein the holders are held by the traction elements.

11. The cooling device of claim 10, wherein the holders are of plate-shaped design, and wherein the traction elements are latchable to the holders.

12. The cooling device of claim 1, wherein the plate-shaped heat sink comprises connection surfaces shaped-adapted to connection poles of the energy accumulator and/or electronic assembly, and wherein the connection surfaces comprise bore- and/or hole-like recesses shape-adapted to pin-like protruding connection journals of a battery and/or a capacitor.

13. The cooling device of claim 1, wherein the first sheet metal blank and the second sheet metal blank have an aluminum oxide (Al₂O₃) coating.

14. An energy accumulator and/or electronic assembly comprising the cooling device of claim 1 for cooling at least one energy accumulator and/or electronic module.

15. The energy accumulator and/or electronic assembly of claim 14, wherein the at least one energy accumulator and/or electronic module is clamped between two heat sinks comprising the plate-shaped heat sink and another heat sink, and wherein the two heat sinks are held against each other by traction elements and are held on the at least one energy accumulator and/or electronic module.

16. The energy accumulator and/or electronic assembly of claim 15, wherein at least one of the two heat sinks is in contact with a connection pole of the at least one energy accumulator and/or electronic module.

17. The energy accumulator and/or electronic assembly of claim 15, wherein two holders separate from the two heat sinks are seated on sides of the two heat sinks facing away from the at least one energy accumulator and/or electronic module and are held on the at least one energy accumulator and/or electronic module by the traction elements.

18. The energy accumulator and/or electronic assembly of claim 15, wherein the traction elements are pull rods.

19. The energy accumulator and/or electronic assembly of claim 15, wherein at least one of the traction elements is latchable in place on at least one of the two heat sinks.

20. The energy accumulator and/or electronic assembly of claim 14, wherein the at least one energy accumulator and/or electronic module comprises a plurality of energy accumulator and/or electronic modules arranged adjacent to each other in a row or in a matrix and are clamped by two common heat sinks on opposite sides.

21. The energy accumulator and/or electronic assembly of claim 14, wherein the at least one energy accumulator and/or electronic module comprises at least one connection pole, wherein the plate-shaped heat sink comprises a connection surface shaped-adapted to the at least one connection pole, and wherein the plate-shaped heat sink comprises an insulating and/or thermally conductive coating comprising a ceramic coating or an aluminum oxide coating.

22. A method of manufacturing a cooling device for cooling an energy accumulator and/or electronic assembly comprising at least one plate-shaped heat sink having at least one coolant channel, wherein the at least one plate-shaped heat sink comprises two sheet metal blanks that are cohesively joined to each other surface to surface by roll bonding, wherein before the two sheet metal blanks are cohesively joined to each other surface to surface by roll bonding, a release agent is provided on at least one of the two sheet metal blanks corresponding to the course of the at least one coolant channel, and wherein after the two sheet metal blanks are cohesively joined to each other surface to surface by roll bonding, at least one of the two sheet metal blanks is bulged by shaping in the region of the release agent in order to form the at least one coolant channel.

23. The method of claim 22, wherein the at least one of the two sheet metal blanks is bulged for forming the at least one coolant channel by inflation and/or by introduction of a pressurized fluid into a joining point between the two sheet metal blanks in the region of the release agent.

24. The method of claim 22, wherein before the two sheet metal blanks are cohesively joined to each other surface to surface by roll bonding, the release agent is printed on a surface of at least one of the two sheet metal blanks by a screen printing process.

25. The method of claim 22, wherein only one of the two sheet metal blanks is bulged for forming the at least one coolant channel.

26. The method of claim 22, wherein an insulating and/or thermally conductive coating is applied onto the at least one plate-shaped heat sink after the two sheet metal blanks are cohesively joined to each other surface to surface by roll bonding.

27. The method of claim 22, wherein on the at least one plate-shaped heat sink a plate-shaped holder is applied which is held by at least one traction element.

28. The method of claim 22, wherein on at least one of the two sheet metal blanks and/or on the at least one plate-shaped heat sink an insulating and/or thermally conductive coating is applied.

29. The method of claim 28, wherein an aluminum oxide coating is applied by plasma coating.
